(19) United States
(12) Patent Application Publication
(10) Pub. No.: US 2026/0059925 A1
(43) Pub. Date: Feb. 26, 2026

(54) LIGHT SOURCE AND WIRING SUBSTRATE

(71) Applicant: NICHIA CORPORATION, Anan-shi (JP)

(72) Inventor: Toshiya OTSUKA, Anan-shi (JP)

(73) Assignee: NICHIA CORPORATION, Anan-shi (JP)

(21) Appl. No.: 19/303,368

(22) Filed: Aug. 19, 2025

(30) Foreign Application Priority Data
Aug. 20, 2024 (JP) 2024-139029

(51) Int. Cl. H10H 29/85; H01L 25/075

(52) U.S. Cl. CPC H10H 29/857; H01L 25/0753

(57) ABSTRACT

A light source including: a wiring substrate including a conductor layer and a first insulating layer arranged on an upper surface of the conductor layer; and first and second light-emitting devices arranged on an upper surface of the wiring substrate. The wiring substrate includes first, second, third, and fourth wiring lines arranged on the first insulating layer. The third and fourth wiring lines are electrically connected to the conductor layer. The first light-emitting device includes a first anode and a first cathode. The second light-emitting device includes a second anode and a second cathode. The first anode is electrically connected to the first wiring line. The first cathode and the second anode are electrically connected to the second wiring line. The second cathode is electrically connected to the third wiring line.

### CROSS-REFERENCE TO RELATED APPLICATIONS

The present application claims priority under 35 U.S.C. § 119 to Japanese Patent Application No.2024-139029, filed Aug. 20, 2024, the content of which is hereby incorporated by reference in its entirety.

### BACKGROUND

### 1. Technical Field

The present disclosure relates to a light source and a wiring substrate.

### 2. Description of Related Art

A light source, in which a plurality of light-emitting elements are arranged in a lattice pattern on a substrate, has been developed (e.g., see Japanese Patent Application Publication No. 2017-502515).

### SUMMARY

One or more embodiments according to the present invention can provide a light source having high heat dissipation, which can be individually driven and controlled, and a wiring substrate.

A light source according to an aspect of the present disclosure includes a wiring substrate, a first light-emitting device, and a second light-emitting device, the wiring substrate including: a conductor layer; a first insulating layer arranged on an upper surface of the conductor layer; and a first wiring line, a second wiring line, a third wiring line, and a fourth wiring line arranged on the first insulating layer, and the first light-emitting device and the second light-emitting device being arranged on an upper surface of the wiring substrate. The third wiring line and the fourth wiring line are electrically connected to the conductor layer. The first light-emitting device includes a first anode and a first cathode. The second light-emitting device includes a second anode and a second cathode. The first anode is electrically connected to the first wiring line. The first cathode and the second anode are electrically connected to the second wiring line. The second cathode is electrically connected to the third wiring line.

According to one or more embodiments of the present disclosure, it is possible to provide a light source having high heat dissipation, which can be individually driven and controlled, and a wiring substrate.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic perspective view of a light source according to a first embodiment.

FIG. 2 is a schematic cross-sectional view taken along the line II-II in FIG. 1.

FIG. 3 is a schematic cross-sectional view taken along the line III-III in FIG. 1.

FIG. 4 is a schematic cross-sectional view taken along the line IV-IV in FIG. 1.

FIG. 5 is a schematic perspective view illustrating a structure of a part of the light source.

FIG. 6 is a schematic cross-sectional view taken along the line VI-VI in FIG. 5.

FIG. 7A is an enlarged schematic plan view illustrating a first unit region U1 in FIG. 5.

FIG. 7B is an enlarged schematic plan view illustrating a second unit region U2 in FIG. 5.

FIG. 8A is a circuit diagram illustrating an aspect of light emission of the light-emitting device.

FIG. 8B is a circuit diagram illustrating an aspect of light emission of the light-emitting device.

FIG. 8C is a circuit diagram illustrating an aspect of light emission of the light-emitting device.

FIG. 8D is a circuit diagram illustrating an aspect of light emission of the light-emitting device.

FIG. 9 is a schematic perspective view of the light source according to an alternative embodiment.

FIG. 10 is a schematic cross-sectional view taken along the line X-X of FIG. 9.

FIG. 11 is a schematic perspective view of a light source according to a second embodiment.

FIG. 12 is a schematic cross-sectional view taken along the line XII-XII in FIG. 11.

FIG. 13 is a schematic perspective view illustrating a structure of a part of the light source.

### DETAILED DESCRIPTION OF EMBODIMENT

A light-emitting device and a method for producing the light-emitting device according to embodiments of the present disclosure are described below with reference to the accompanying drawings. The following embodiments are examples of the light-emitting device and the method for producing the light-emitting device embodying technical concepts of the present embodiments, and limitation to the embodiments described below is not intended. Dimensions, materials, shapes, relative arrangements, or the like of constituent members described in the embodiments are not intended to limit the scope of the present disclosure thereto, unless otherwise specified, and are merely exemplary. The sizes, positional relationship, or the like of members illustrated in each of the drawings may be exaggerated for clarity of description. In the following description, members having the same terms and reference characters represent the same members or members of the same quality, and a detailed description of these members is omitted as appropriate. As a cross-sectional view, an end view illustrating only a cut surface may be illustrated.

In the following description, terms indicating specific directions or positions (for example, “upper”, “lower”, and other terms including these terms) may be used. However, these terms are used merely to make it easy to understand relative directions or positions in the referenced drawing. As long as the relative direction or position is the same as that described in the referenced drawing using the term such as “upper” or “lower”, in drawings other than the drawings of the present disclosure, actual products, and the like, components need not be arranged in the same manner as that in the referenced drawing. For example, on the assumption that when two members are present, the positional relationship expressed as “upper (or lower)” in the present specification may include a case in which the two members are in contact with each other and a case in which the two members are not in contact with each other and one of the two members is located above (or below) the other member. Note that a plan view refers to viewing directly or in a see-through manner from the upper or lower side. Further, in the present specification, unless otherwise specified, a case in which a member covers an object to be covered includes a case in which the member is in contact with the object to be covered and directly covers the object to be covered, and a case in which the member is not in contact with the object to be covered and indirectly covers the object to be covered.

### First Embodiment

### Light Source 100

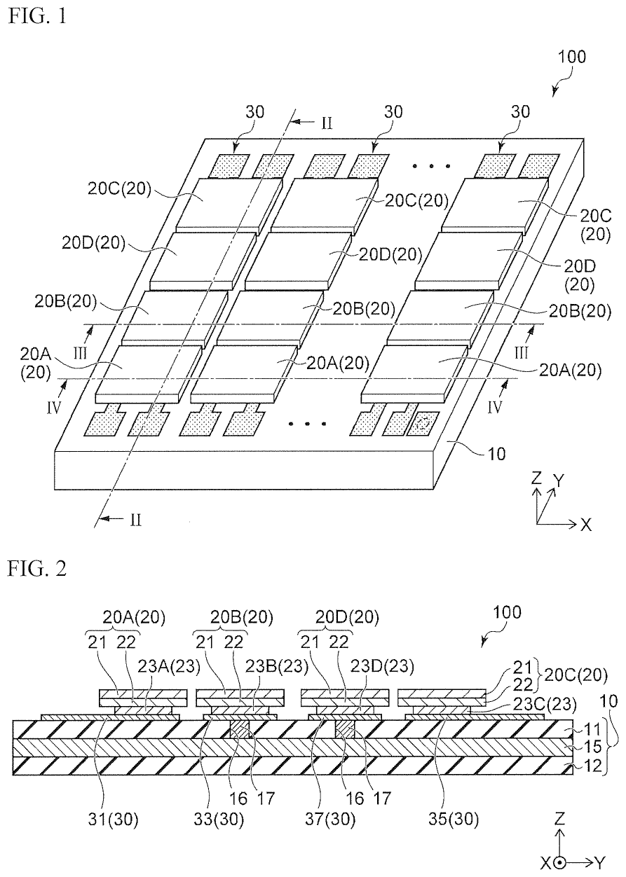

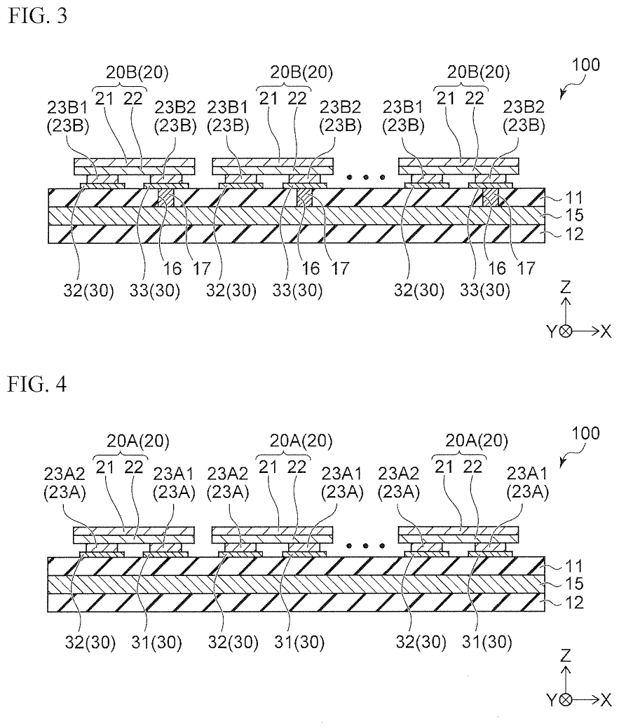

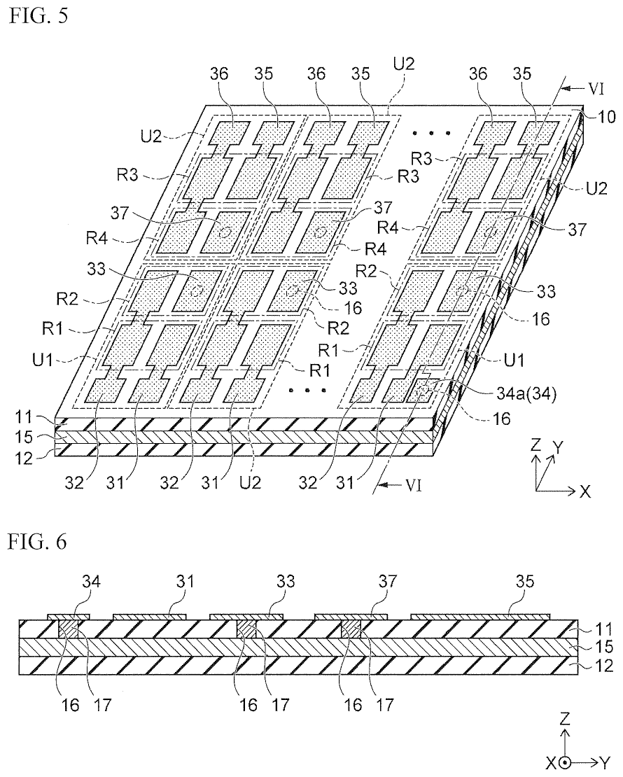

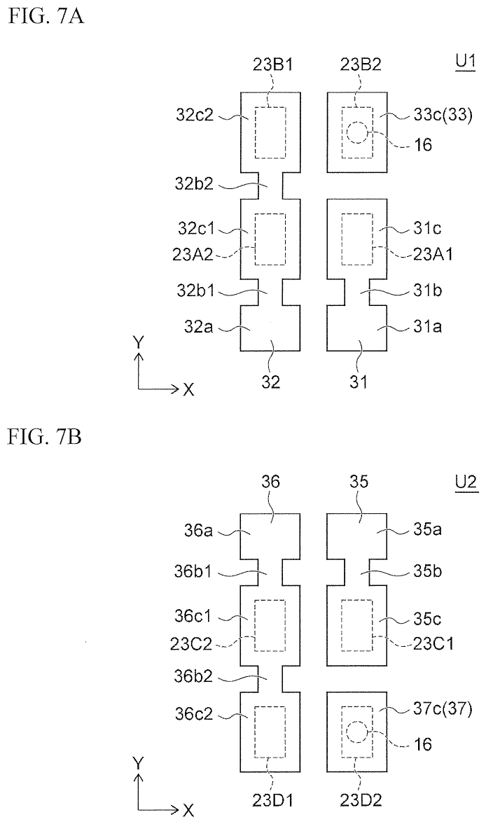

A configuration of a light source 100 in the present disclosure will be described below. FIG. 1 is a schematic perspective view of the light source 100 according to a first embodiment. FIG. 2 is a schematic cross-sectional view taken along the line II-II in FIG. 1. FIG. 3 is a schematic cross-sectional view taken along the line III-III in FIG. 1. FIG. 4 is a schematic cross-sectional view taken along the line IV-IV in FIG. 1. FIG. 5 is a schematic perspective view illustrating a structure of a part of the light source 100. FIG. 6 is a schematic cross-sectional view taken along the line VI-VI in FIG. 5. FIG. 7A is an enlarged schematic plan view illustrating a first unit region U1 in FIG. 5. FIG. 7B is an enlarged schematic plan view illustrating a second unit region U2 in FIG. 5.

The light source 100 includes a wiring substrate 10 and a plurality of light-emitting devices 20 arranged on the upper surface of the wiring substrate 10. In a plan view, the wiring substrate 10 is formed in a rectangular shape, and the plurality of light-emitting devices 20 are arranged in a lattice pattern on the wiring substrate 10. In the present embodiment, four light-emitting devices 20 are arranged along the first direction (a Y direction in the drawing; hereinafter simply referred to as the Y direction) in a plan view. Note that n light-emitting devices 20 (n is a natural number; the same applies hereinafter) are arranged along the second direction (an X direction in the drawing; hereinafter simply referred to as the X direction) orthogonal to the first direction in a plan view.

More specifically, the light-emitting device 20 includes a first light-emitting device 20A, a second light-emitting device 20B, a third light-emitting device 20C, and a fourth light-emitting device 20D. The plurality of light-emitting devices 20 are arranged on the upper surface of the wiring substrate 10 such that n combinations of the first light-emitting device 20A, the second light-emitting device 20B, the fourth light-emitting device 20D, and the third light-emitting device 20C arranged in this order along the Y direction are arranged along the X direction.

### Wiring Substrate 10

The wiring substrate 10 is a member that supports the light-emitting device 20 and the like. In the present embodiment, the planar shape of the wiring substrate 10 is rectangular, but not limited to this aspect and can have various shapes such as a circle, an ellipse, a polygon, such as a hexagon, or a polygon with rounded corners. Among them, a rectangular shape is preferable. The size of the wiring substrate 10 can be appropriately adjusted depending on the required performance such as the sizes and the number of the light-emitting devices 20 to be arranged thereon.

The wiring substrate 10 includes a conductor layer 15, a first insulating layer 11 arranged on the upper surface of the conductor layer 15, a second insulating layer 12 arranged on the lower surface of the conductor layer 15, and a wiring line 30 arranged on the first insulating layer 11. Main materials for the first insulating layer 11 and the second insulating layer 12 are insulating materials and are preferably materials through which light from the light-emitting device 20 and light from the outside are less likely to be transmitted. Examples of such a material include: oxide-based ceramics such as aluminum oxide, silicon oxide, calcium oxide, and magnesium oxide; nitride-based ceramics such as aluminum nitride, silicon nitride, and boron nitride; ceramics such as silicon carbide, mullite, and borosilicate glass; and resins such as a phenolic resin, an epoxy resin, a silicone resin, a polyimide resin, a bismaleimide triazine resin (BT resin), and polyphtalamide. When a resin is used, inorganic fillers such as glass fibers, silicon oxide, titanium oxide, and aluminum oxide can be mixed into the resin, as necessary. This can improve the mechanical strength, reduce the coefficient of thermal expansion, and improve the light reflectance. Examples of the main material of the conductor layer 15 include metals such as Au, Ag, Cu, Fe, Ti, Pd, Ni, Cr, Pt, W, and Al, or alloys containing these metals.

### Light-Emitting Device 20

The light-emitting device 20 includes a light-emitting element 22 such as a light-emitting diode, and a light-transmissive member 21 arranged on the light-emitting element 22. The light-emitting element 22 includes, for example, an element substrate made of sapphire or the like and a semiconductor layer formed thereon. Alternatively, the light-emitting element 22 can be formed of a semiconductor element made of only a semiconductor layer without including an element substrate. The shape of the light-emitting element 22 in a plan view can be a polygon such as a triangle, a quadrangle, or a hexagon. The size of the light-emitting element 22 can be, for example, in a range from 100 μm to 3000 μm per side in a plan view. Specifically, the light-emitting element 22 can be a square with a side of about 600 μm, about 1000 μm, about 1400 μm, about 1700 μm, or the like. The light-emitting element 22 can be a rectangular shape with the long sides and short sides in a plan view.

The size, emission wavelength, composition, and the like of each of the light-emitting elements 22 can be the same, or different in some or all of these. All of the plurality of light-emitting elements 22 can be connected in series or in parallel and can be connected such that the series connections and parallel connections are mixed.

The light-emitting element 22 includes an n-type semiconductor layer, a p-type semiconductor layer, and a light-emitting layer interposed therebetween. The semiconductor layered body including such a light-emitting layer is, for example, InₓAl_{y}Ga_{1-x-y}N (0≤x, 0≤y, and x+y≤1).

The light-emitting element 22 can have a structure in which one or more light-emitting layers are interposed between the n-type semiconductor layer and the p-type semiconductor layer, or can have a structure in which the n-type semiconductor layer, the light-emitting layer, and the p-type semiconductor layer are sequentially repeated multiple times. In a case in which the light-emitting element 22 includes the plurality of light-emitting layers, the light-emitting element 22 can include the plurality of light-emitting layers having different light emission peak wavelengths, or can include the plurality of light-emitting layers having the same light emission peak wavelengths. The expression “having the same light emission peak wavelengths” includes cases in which there are variations of several nanometers. A combination of light emission peak wavelengths between the plurality of light-emitting layers can be selected as appropriate. For example, in a case in which the semiconductor layered body includes two light-emitting layers, light-emitting layers can be selected from combinations of the same color, such as blue light and blue light, green light and green light, red light and red light, ultraviolet light and ultraviolet light, as well as combinations of different emission color, such as blue light and green light, blue light and red light, or green light and red light.

The light-emitting device 20 includes at least a pair of electrodes 23 on the lower surface side of the light-emitting element 22. In other words, as electrodes, the light-emitting device 20 includes at least one anode and at least one cathode. As an example, the anode and the cathode each has a rectangular shape in a plan view. In a case in which there is one anode and one cathode, the size of each can be increased. This can improve the heat dissipation.

Specifically, the first light-emitting device 20A includes, as first electrodes 23A, a first anode 23A1 and a first cathode 23A2. The second light-emitting device 20B includes, as second electrodes 23B, a second anode 23B1 and a second cathode 23B2. The third light-emitting device 20C includes, as third electrodes 23C, a third anode 23C1 and a third cathode 23C2. The fourth light-emitting device 20D includes, as fourth electrodes 23D, a fourth anode 23D1 and a fourth cathode 23D2.

The first light-emitting device 20A is arranged in a first region R1 on the upper surface of the first insulating layer 11. The second light-emitting device 20B is arranged in a second region R2 on the upper surface of the first insulating layer 11. The third light-emitting device 20C is arranged in a third region R3 on the upper surface of the first insulating layer 11. The fourth light-emitting device 20D is arranged in a fourth region R4 on the upper surface of the first insulating layer 11. The first region R1, the second region R2, the third region R3, and the fourth region R4 are arranged in the order of the first region R1, the second region R2, the fourth region R4, and the third region R3 along the Y direction. Further, n combinations of the first region R1, the second region R2, the third region R3, and the fourth region R4 are arranged along the X direction while maintaining the order.

A good electrical conductor can be used for the electrodes 23, and the electrodes 23 can be made of, for example, gold, silver, copper, platinum, iron, nickel, or tin, or alloys of these metals. The electrodes 23 can include an ohmic electrode in contact with the lower surface of the light-emitting element 22 and a pad electrode connected to the ohmic electrode and connected to the outside. The thickness of the electrodes 23 can be set, for example, in a range from 0.5 μm to 50 μm, preferably in a range from 5 μm to 20 μm.

The light-transmissive member 21 is a member that transmits light emitted from the light-emitting element 22 and emits the light to the outside and is bonded to the upper surface of the light-emitting element 22. Examples of the light-transmissive member 21 include a member that transmits 60% or greater of light from the light-emitting element 22 (for example, light with a wavelength in a range from 320 nm to 850 nm), and preferably include a member that transmits 70% or greater of the light. In addition, the light-transmissive member 21 is preferably a plate-shaped member.

The thickness of the light-transmissive member 21 can be, for example, in a range from 50 μm to 300 μm. The light-transmissive member 21 and the light-emitting element 22 can be bonded using a light-transmissive adhesive or the like, which is commonly used in the art. The light-transmissive member 21 and the light-emitting element 22 can be bonded to each other by a direct bonding method using pressure bonding, surface activation bonding, atomic diffusion bonding, or hydroxyl group bonding.

The light-transmissive member 21 can be formed of an inorganic material such as glass, ceramics, or sapphire, or an organic material such as a resin or a hybrid resin containing one or more of silicone resins, modified silicone resins, epoxy resins, modified epoxy resins, acrylic resins, phenolic resins, and fluororesins.

The light-transmissive member 21 can include a light diffusing material and a phosphor that can convert a wavelength of at least a part of the incident light. Examples of the light-transmissive member containing a phosphor include a sintered compact of a phosphor, resin, glass, ceramics, or another inorganic material, which contains a phosphor. A resin layer containing a phosphor can be formed on the surface of a molded body of resin, glass, ceramics, or the like.

As the light diffusing material, any of those commonly used in the art, such as fillers of titanium oxide, barium titanate, aluminum oxide, silicon oxide, zirconium oxide, Aerosil, glass, glass fiber, or wollastonite, as well as aluminum nitride, can be used.

A phosphor that can be excited by light emitted from the light-emitting element 22 is used. For example, examples of the phosphor that can be excited by light emitted from a blue light-emitting element or an ultraviolet light-emitting element include cerium activated yttrium aluminum garnet based phosphors (YAG:Ce), cerium activated lutetium aluminum garnet based phosphors (LAG:Ce), europium and/or chromium activated nitrogen-containing calcium alumino silica based phosphors (CaO—Al₂O₃—SiO₂:Eu), europium activated silicate based phosphors ((Sr, Ba)₂SiO₄:Eu), β-SiAlON phosphor, CASN based phosphors represented by CaAlSiN₃:Eu, nitride based phosphors such as SCASN based phosphors represented by (Sr, Ca)AlSiN₃:Eu, KSF based phosphors represented by K₂SiF₆:Mn, sulfide based phosphors, and quantum dot phosphors. When these phosphors are combined with a blue light-emitting element or an ultraviolet light-emitting element, a light-emitting device of a desired light emission color (for example, a white light-emitting device) can be produced.

### Wiring Line 30

The wiring line 30 is arranged on the first insulating layer 11 in a predetermined pattern and is electrically connected to the plurality of light-emitting devices 20.

Examples of the material of the wiring line include metals such as Au, Ag, Cu, Fe, Ti, Pd, Ni, Cr, Pt, W, Al, and Sn, or alloys containing these metals. The wiring lines can be formed by plating, vapor deposition, sputtering, or the like. For example, in a case in which Au is used as a bonding member to be described below between the light-emitting element and the substrate, Au is preferably used for the outermost surface of the wiring line 30 from the viewpoint of improving bondability.

The wiring line 30 includes a first wiring line 31, a second wiring line 32, a third wiring line 33, a fourth wiring line 34, a fifth wiring line 35, a sixth wiring line 36, and a seventh wiring line 37 arranged on the first insulating layer 11. The first wiring line 31, the second wiring line 32, and the third wiring line 33 are included in the first unit region U1. The fifth wiring line 35, the sixth wiring line 36, and the seventh wiring line 37 are included in the second unit region U2. The first unit region U1 and the second unit region U2 are arranged in the order of the first unit region U1 and the second unit region U2 along the Y direction. Further, n combinations of the first unit region U1 and the second unit region U2 are arranged along the X direction while maintaining the order.

In the first unit region U1, the second wiring line 32, the first wiring line 31, and the third wiring line 33 are arranged side by side along the X direction. Specifically, the second wiring line 32 is arranged on a negative side in the X direction, the first wiring line 31 is arranged on a negative side in the Y direction on a positive side in the X direction, and the third wiring line 33 is arranged on a positive side in the Y direction on the positive side in the X direction.

In the second unit region U2, the sixth wiring line 36, the fifth wiring line 35, and the seventh wiring line 37 are arranged side by side along the X direction. Specifically, the sixth wiring line 36 is arranged on the negative side in the X direction, the seventh wiring line 37 is arranged on the negative side in the Y direction on the positive side in the X direction, and the fifth wiring line 35 is arranged on the positive side in the Y direction on the positive side in the X direction.

The first wiring line 31 includes a pad 31a through which a bonding wire for conducting electricity from the outside is connected, a terminal 31c to which the first anode 23A1 of the first light-emitting device 20A is electrically connected, and a coupling portion 31b for coupling the pad 31a and the terminal 31c. The pad 31a, the coupling portion 31b, and the terminal 31c are arranged in this order along the Y direction. As an example, the pad 31a and the terminal 31c have a rectangular shape in a plan view, and the width of the pad 31a along the X direction (hereinafter, also simply referred to as the width) is about the same as the width of the terminal 31c but is not limited to this aspect. In addition, as an example, the width of the coupling portion 31b is narrower than the width of the pad 31a and the terminal 31c but is not limited to this aspect.

The second wiring line 32 includes a pad 32a to which a bonding wire for conducting electricity from the outside is connected, a first terminal 32c1 to which the first cathode 23A2 of the first light-emitting device 20A is electrically connected, a second terminal 32c2 to which the second anode 23B1 of the second light-emitting device 20B is electrically connected, a first coupling portion 32b1 for coupling the pad 32a and the first terminal 32c1, and a second coupling portion 32b2 for coupling the first terminal 32c1 and second terminal 32c2.

The pad 32a, the first coupling portion 32b1, the second coupling portion 32b2, the first terminal 32c1, and the second terminal 32c2 are arranged along the Y direction in the order of the pad 32a, the first coupling portion 32b1, the first terminal 32c1, the second coupling portion 32b2, and the second terminal 32c2. As an example, the pad 32a, the first terminal 32c1, and the second terminal 32c2 have a rectangular shape in a plan view, and the width of the pad 32a is approximately the same as the widths of the first terminal 32c1 and the second terminal 32c2 but is not limited to this aspect. In addition, as an example, the widths of the first coupling portion 32b1 and the second coupling portion 32b2 are narrower than the widths of the pad 32a, the first terminal 32c1, and the second terminal 32c2, but is not limited to this aspect.

The third wiring line 33 includes a terminal 33c to which the second cathode 23B2 of the second light-emitting device 20B is electrically connected. As an example, the terminal 33c has a rectangular shape in a plan view, but is not limited to this aspect. A through hole 16 is formed in the first insulating layer 11 immediately below the third wiring line 33. A metal member 17 is arranged inside the through hole 16, and the third wiring line 33 and the conductor layer 15 are electrically connected via the metal member 17.

Due to such a configuration, in the first unit region U1, the pad 31a of the first wiring line 31, the first anode 23A1 of the first light-emitting device 20A, and the second cathode 23B2 of the second light-emitting device 20B are arranged along the Y direction in a plan view. The pad 32a of the second wiring line 32, the first cathode 23A2 of the first light-emitting device 20A, and the second anode 23B1 of the second light-emitting device 20B are arranged along the Y direction.

At least one fourth wiring line 34 is arranged on the wiring substrate 10. As an example, the fourth wiring line 34 is arranged at one of the four corners of the upper surface of the wiring substrate 10 (specifically, an end portion on the positive side in the X direction and the negative side in the Y direction) but is not limited to this aspect. The fourth wiring line 34 includes a pad 34a to which a bonding wire having the same potential as the ground is connected. As an example, the pad 34a has a rectangular shape in a plan view but is not limited to this aspect. The through hole 16 is formed in the first insulating layer 11 immediately below the fourth wiring line 34. The metal member 17 is arranged inside the through hole 16, and the fourth wiring line 34 and the conductor layer 15 are electrically connected via the metal member 17.

The fifth wiring line 35 includes a pad 35a to which a bonding wire for conducting electricity from the outside is connected, a terminal 35c to which the third anode 23C1 of the third light-emitting device 20C is electrically connected, and a coupling portion 35b for coupling the pad 35a and the terminal 35c. The pad 35a, the coupling portion 35b, and the terminal 35c are arranged along the Y direction in the order of the terminal 35c, the coupling portion 35b, and the pad 35a. As an example, the pad 35a and the terminal 35c have a rectangular shape in a plan view, and the width of the pad 35a is approximately the same as the width of the terminal 35c but is not limited to this aspect. In addition, as an example, the width of the coupling portion 35b is narrower than the width of the pad 35a and the terminal 35c but is not limited to this aspect.

The sixth wiring line 36 includes a pad 36a to which a bonding wire for conducting electricity from the outside is connected, a first terminal 36c1 to which the third cathode 23C2 of the third light-emitting device 20C is electrically connected, a second terminal 36c2 to which the fourth anode 23D1 of the fourth light-emitting device 20D is electrically connected, a first coupling portion 36b1 for coupling the pad 36a and the first terminal 36c1, and a second coupling portion 36b2 for coupling the first terminal 36c and the second terminal 36c2.

The pad 36a, the first coupling portion 36b1, the second coupling portion 36b2, the first terminal 36c1, and the second terminal 36c2 are arranged along the Y direction in the order of the second terminal 36c2, the second coupling portion 36b2, the first terminal 36c1, the first coupling portion 36b1, and the pad 36a. As an example, the pad 36a, the first terminal 36c1, and the second terminal 36c2 have a rectangular shape in a plan view, and the width of the pad 36a is approximately the same as the width of the first terminal 36c1 and the second terminal 36c2 but is not limited to this aspect. In addition, as an example, the widths of the first coupling portion 36b1 and the second coupling portion 36b2 are narrower than the widths of the pad 36a, the first terminal 36c1, and the second terminal 36c2, but is not limited to this aspect.

The seventh wiring line 37 includes a terminal 37c to which the fourth cathode 23D2 of the fourth light-emitting device 20D is electrically connected. As an example, the terminal 37c has a rectangular shape in a plan view but is not limited to this aspect. The through hole 16 is formed in the first insulating layer 11 immediately below the seventh wiring line 37. The metal member 17 is arranged inside the through hole 16, and the seventh wiring line 37 and the conductor layer 15 are electrically connected via the metal member 17.

Due to such a configuration, in the second unit region U2, the fourth cathode 23D2 of the fourth light-emitting device 20D, the third anode 23C1 of the third light-emitting device 20C, and the pad 35a of the fifth wiring line 35 are arranged along the Y direction in a plan view. In addition, the fourth anode 23D1 of the fourth light-emitting device 20D, the third cathode 23C2 of the third light-emitting device 20C, and the pad 36a of the sixth wiring line 36 are arranged along the Y direction.

### Light Emission Control

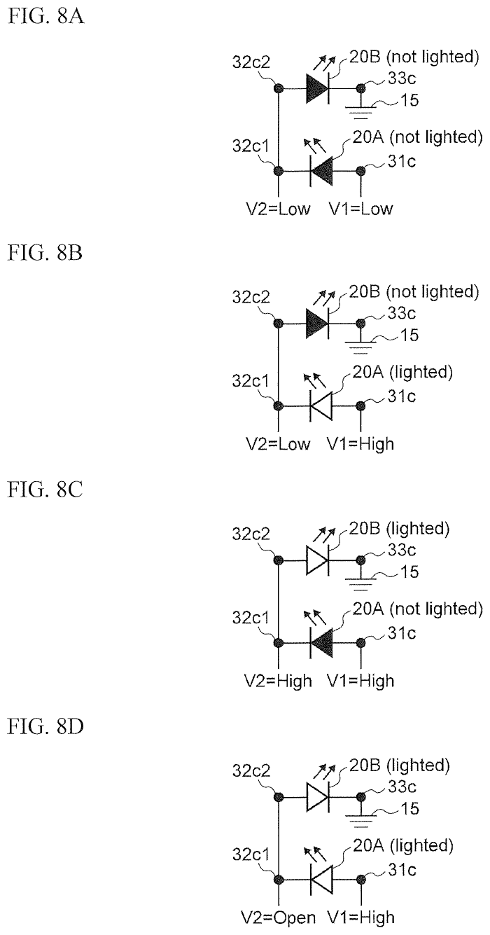

Light emission control of the light source 100 will be described with reference to FIGS. 8A to 8D. FIGS. 8A to 8D are circuit diagrams illustrating aspects of light emission of the light-emitting device 20. Although light emission control of the first light-emitting device 20A and the second light-emitting device 20B in the first unit region U1 will be described below, the third light-emitting device 20C and the fourth light-emitting device 20D in the second unit region U2 can be controlled in the same manner.

As described above, the first light-emitting device 20A is electrically connected to the terminal 31c of the first wiring line 31 and the first terminal 32c1 of the second wiring line 32. The second light-emitting device 20B is electrically connected to the second terminal 32c2 of the second wiring line 32 and the terminal 33c of the third wiring line 33. The third wiring line 33 is electrically connected to the conductor layer 15, and the conductor layer 15 is connected to the ground via the fourth wiring line 34. In the following description, the potential of the first wiring line 31 is referred to as a first potential V1, and the potential of the second wiring line 32 is referred to as a second potential V2.

As illustrated in FIG. 8A, in a case in which the first potential V1 is Low (a potential approximately equal to the ground) and the second potential V2 is Low, no potential difference (voltage) is generated between the terminal 31c of the first wiring line 31 and the first terminal 32c1 of the second wiring line 32, and thus no current flows through the first light-emitting device 20A. In addition, since no potential difference is generated between the second terminal 32c2 of the second wiring line 32 and the terminal 33c of the third wiring line 33, no current flows through the second light-emitting devices 20B either. Therefore, neither the first light-emitting device 20A nor the second light-emitting device 20B emits light.

As illustrated in FIG. 8B, in a case in which the first potential V1 is High (a potential equal to or higher than the forward voltage Vf of the light-emitting element 22 with Low as the reference) and the second potential V2 is Low, a potential difference is generated between the terminal 31c of the first wiring line 31 and the first terminal 32c1 of the second wiring line 32, so that a current flows through the first light-emitting device 20A. On the other hand, no potential difference is generated between the second terminal 32c2 of the second wiring line 32 and the terminal 33c of the third wiring line 33, and thus no current flows through the second light-emitting device 20B. Therefore, only the first light-emitting device 20A emits light.

As illustrated in FIG. 8C, in a case in which the first potential V1 is High and the second potential V2 is High, no potential difference is generated between the terminal 31c of the first wiring line 31 and the first terminal 32c1 of the second wiring line 32, and thus no current flows through the first light-emitting device 20A. On the other hand, since a potential difference is generated between the second terminal 32c2 of the second wiring line 32 and the terminal 33c of the third wiring line 33, a current flows through the second light-emitting device 20B. Therefore, only the second light-emitting device 20B emits light.

As illustrated in FIG. 8D, in a case in which the first potential V1 is High and the second potential V2 is Open (a state in which the terminals are not connected), a potential difference is generated between the terminal 31c of the first wiring line 31 and the terminal 33c of the third wiring line 33, and thus a current flows through the first light-emitting device 20A and the second light-emitting device 20B. Therefore, both the first light-emitting device 20A and the second light-emitting device 20B emit light.

### Interim Summary

As described above, the light source 100 according to the present embodiment includes the wiring substrate 10 including the conductor layer 15, the first insulating layer 11 arranged on the upper surface of the conductor layer 15, the first wiring line 31, the second wiring line 32, the third wiring line 33, and the fourth wiring line 34 arranged on the first insulating layer 11, and the first light-emitting device 20A and the second light-emitting device 20B arranged on the upper surface of the wiring substrate 10. The third wiring line 33 and the fourth wiring line 34 are electrically connected to the conductor layer 15. The first light-emitting device 20A includes the first anode 23A1 and the first cathode 23A2, and the second light-emitting device 20B includes the second anode 23B1 and the second cathode 23B2. The first anode 23A1 is electrically connected to the first wiring line 31, the first cathode 23A2 and the second anode 23B1 are electrically connected to the second wiring line 32, and the second cathode 23B2 is electrically connected to the third wiring line 33. With such a configuration, a plurality of wiring lines can be arranged on the upper surface of the wiring substrate 10 while the wiring substrate 10 includes the conductor layer 15 having high thermal conductivity, and it is possible to provide the high-density light source having high heat dissipation, which can be individually driven and controlled.

In addition, the following configuration is possible: in a plan view, the first wiring line 31 and the second wiring line 32 can be arranged side by side along the second direction (X direction) orthogonal to the first direction (Y direction), the pad 31a of the first wiring line 31, the first anode 23A1 of the first light-emitting device 20A, and the second cathode 23B2 of the second light-emitting device 20B can be arranged along the Y direction, and the pad 32a of the second wiring line 32, the first cathode 23A2 of the first light-emitting device 20A, and the second anode 23B1 of the second light-emitting device 20B can be arranged along the Y direction. With such a configuration, light emission control can be performed to cause the first light-emitting device 20A and/or the second light-emitting device 20B to emit light.

In addition, the wiring substrate 10 can further include a second insulating layer 12 arranged on the lower surface of the conductor layer 15. With such a configuration, controlling the potential of the conductor layer 15 and, for example, maintaining the potential at the ground becomes easy.

Further, the first insulating layer 11 can include a plurality of through holes 16, and inside the through holes 16, the metal members 17 can be arranged. The third wiring line 33 and the fourth wiring line 34 can be electrically connected to the conductor layer 15 via the metal members 17 arranged inside the through holes 16. Such a configuration allows the third wiring line 33 and the fourth wiring line 34 to be electrically connected to the conductor layer 15 with a simple structure, and the cost required for installing the wiring lines can thus be suppressed.

Note that the light sources 100 can further include the third light-emitting device 20C and the fourth light-emitting device 20D arranged on the upper surface of the wiring substrate 10. In this case, the wiring substrate 10 further includes the fifth wiring line 35, the sixth wiring line 36, and the seventh wiring line 37 arranged on the first insulating layer 11. The seventh wiring line 37 is electrically connected to the conductor layer 15 via the metal member 17 arranged inside the through hole 16. The first light-emitting device 20A, the second light-emitting device 20B, the fourth light-emitting device 20D, and the third light-emitting device 20C are arranged along the Y direction. The third light-emitting device 20C includes the third anode 23C1 and the third cathode 23C2, and the fourth light-emitting device 20D includes the fourth anode 23D1 and the fourth cathode 23D2. The third anode 23C1 is electrically connected to the fifth wiring line 35, the third cathode 23C2 and the fourth anode 23D1 are electrically connected to the sixth wiring line 36, and the fourth cathode 23D2 is electrically connected to the seventh wiring line 37. With such a configuration, it is possible to provide a high-density light source having high heat dissipation, which can be individually driven and controlled while accommodating a greater number of light-emitting devices 20.

### Alternative Embodiment

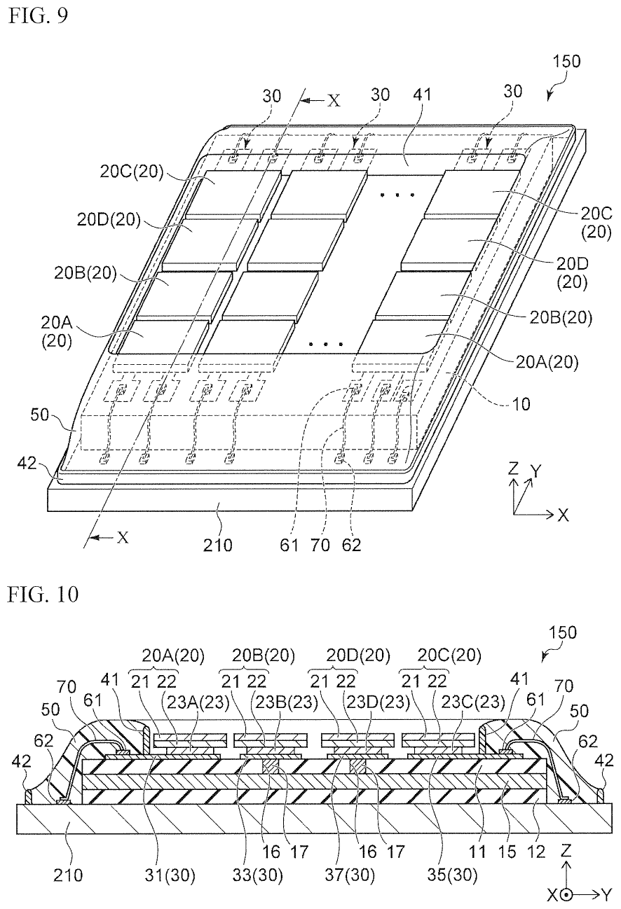

A light source 150 according to an alternative embodiment of the first embodiment will be described with reference to FIGS. 9 and 10. In the following description, differences from the first embodiment are mainly described. FIG. 9 is a schematic perspective view illustrating the light source 150 according to the alternative embodiment. FIG. 10 is a schematic cross-sectional view taken along the line X-X in FIG. 9.

The light source 150 according to the alternative embodiment further includes a base substrate 210 and a covering member 50. The base substrate 210 includes a flat plate-shaped base material and a second terminal 62 arranged on an upper surface of the base material. The base substrate 210 includes a substrate placement region on an upper surface thereof in which the wiring substrate 10 is placed.

The second terminal 62 is connected by a wire 70 to a first terminal 61 arranged on the wiring line 30 on the upper surface of the wiring substrate 10. The first terminal 61 and the second terminal 62 are, as an example here, arranged such that each is substantially rectangular in shape, spaced apart from one another, and aligned in a single row along the X direction. The interval at which each of the first terminal 61 and the second terminal 62 is aligned can be in a range from 50 μm to 200 μm. The first terminal 61 and the second terminal 62 can be formed, for example, by a material and a forming method similar to that of the wiring line of the wiring substrate 10 described above.

The base substrate 210 is preferably made of a material having high heat dissipation, and more preferably, a material that also has high light-shielding properties and base material strength. Specifically, examples of a material of the base material include oxide-based ceramics such as aluminum oxide, silicon oxide, calcium oxide, and magnesium oxide, and nitride-based ceramics such as aluminum nitride, silicon nitride, and boron nitride, ceramics such as silicon carbide, mullite, and borosilicate glass, resins such as phenolic resin, epoxy resin, polyimide resin, BT resin, and polyphtalamide, in addition, a composite material formed of a resin and a metal or ceramic. A flat plate-like base material can be used, and a base material with a cavity in the upper surface can be used. In this case, the wiring substrate 10 can be placed inside the cavity with the bottom of the cavity in the base substrate 210 serving as the substrate placement region. The base substrate 210 can include wiring lines for placing the wiring substrate 10 on the surface of the substrate placement region. The wiring substrate 10 and the base substrate 210 can be bonded via a bonding material such as an Ag sintered compact, solder, adhesive resin, and the like.

Examples of the wire 70 include an electrically conductive wire made of a metal such as gold, copper, platinum, and aluminum and/or an alloy containing at least one of these metals. In particular, gold having excellent thermal resistance and the like is preferably used. The diameter of the wire 70 is, for example, in a range from 10 μm to 50 μm.

The covering member 50 is a light-shielding resin that covers the wire 70 on the outer side of the plurality of light-emitting devices 20 in a plan view. The covering member 50 is arranged in contact with a first protrusion 41 to be described below. The covering member 50 has a wider width on the long side of the substantially rectangular wiring substrate 10 in a plan view than in the region on the short side. Furthermore, the height of the covering member 50 (that is, the distance from an upper surface of the base substrate 210 to an upper surface of the covering member 50) is arranged to be the highest at a position directly above the top portion of the wire 70 (here, the loop top of the wire 70). Note that the position of the top portion of the covering member 50 is arranged so as to be positioned above the top portion of the first protrusion 41, which will be described below.

Examples of the covering member 50 having light-shielding properties include a resin containing a filler having light-shielding properties. Examples of the resin serving as a base material that can be used include a silicone resin, a modified silicone resin, an epoxy resin, a modified epoxy resin, and an acrylic resin. Examples of the filler having light-shielding properties include light absorbing substances such as pigment, carbon black, graphite, and the like; light-reflective substances similar to the light-reflective substances included in the reflective member described above; and the like. Specific examples include white resin having excellent light reflectivity, black resin having excellent light absorbency, and gray resin having light reflectivity and light absorbency. Note that the covering member 50 can have these resin layers layered a plurality of times. Among these, considering the deterioration of resin due to light absorption, it is preferable to use a white resin having light reflectivity at least on the outermost surface of the covering member 50.

The light source 150 includes, on the wiring substrate 10, a first protrusion 41 having transmissivity in contact with the covering member 50. Further, the light source 150 is arranged on the upper surface of the base substrate 210 outside the second terminal 62 and includes a second protrusion 42 in contact with the covering member 50. That is, the covering member 50 is arranged between the first protrusion 41 and the second protrusion 42, extending from the upper surface of the wiring substrate 10 to the upper surface of the base substrate 210.

The covering member 50 is arranged between the first protrusion 41 on the wiring substrate 10 and the second protrusion 42 on the base substrate 210. Such an arrangement of the covering member 50 can be formed by supplying uncured resin, which constitutes the covering member 50, into a frame surrounded by the first protrusion 41 and the second protrusion 42. In other words, the first protrusion 41 and the second protrusion 42 can be used as dams to block the flow of the uncured resin when the covering member 50 is supplied.

The first protrusion 41 and the second protrusion 42 can have a predetermined height by providing a plurality of layers of the uncured resin in the height direction. For example, the first protrusion 41 and the second protrusion 42 can be formed to a predetermined height by arranging one layer of a resin adjusted to a predetermined viscosity from the nozzle onto the substrate and repeating the operation.

The first protrusion 41 is arranged on the wiring substrate 10 such that the top portion thereof is positioned above the light-emitting device 20. The height of the first protrusion 41 from the upper surface of the wiring substrate 10 can be the same as or different from the height of the second protrusion 42 from the upper surface of the base substrate 210. In a case in which they are different from each other, it is preferable that the second protrusion 42 be higher than the first protrusion 41. In this case, the difference between the height from the upper surface of the base substrate 210 to the top portion of the first protrusion 41 and the height from the upper surface of the base substrate 210 to the top portion of the second protrusion 42 can be made smaller than the thickness of the wiring substrate 10 (that is, the distance from the upper surface to the lower surface of the wiring substrate 10). Accordingly, when the covering member 50 is arranged between the first protrusion 41 and the second protrusion 42, the uncured covering member 50 overflowing to the outside of the second protrusion 42 can be suppressed.

The first protrusion 41 and the second protrusion 42 can be made of the resin exemplified as the base material of the above-described covering member. Note that it is preferable to use a resin forming the first protrusion 41 and the second protrusion 42 having higher viscosity than the resin forming the covering member 50. The viscosity of the resin can be adjusted by, for example, adjusting the amount of a filler for viscosity adjustment contained in the resin.

The first protrusion 41 has transmissivity to the light emitted from the light-emitting device 20. The first protrusion 41 can preferably be made of a resin material having both light transmissivity and insulation properties, such as a thermosetting resin like an epoxy resin or a silicone resin. The first protrusion 41 is arranged in a rectangular frame shape in a plan view. As an example, the covering member 50 is arranged in contact with the top portion of the first protrusion 41. The first protrusion 41 is arranged in a rectangular frame shape in a plan view on the wiring substrate 10 along an outer periphery of a region (hereinafter, also referred to as an arrangement region) in which the plurality of light-emitting devices 20 are arranged. At a position along the longitudinal direction of the arrangement region, the first protrusion 41 is arranged between a side in the longitudinal direction of the arrangement region and the plurality of first terminals 61. Note that the first protrusion 41 is arranged between the arrangement region and the outer edge of a first substrate on the wiring substrate 10 at a position along the transverse direction of the arrangement region.

Note that the first protrusion 41 preferably includes an inclined surface that is inclined from a side of the substrate toward the top portion of the first protrusion 41. The inclined surface is preferably a curved surface protruding outward. Specifically, the cross-sectional shape of the first protrusion 41 is preferably a semicircular shape or a semielliptical shape. Thus, the surface of the covering member 50 in contact with the first protrusion 41 can be a curved surface protruding toward a side of the covering member 50. Since the covering member 50 has such a surface shape, light emitted from the light-emitting device 20, transmitted through the first protrusion 41, and directed to the covering member 50 can be reflected to a side of the wiring substrate 10. As a result, unintended leakage light or stray light is suppressed from traveling upward (toward a side of light extraction), and thus a light-emitting module in which light scattering is suppressed can be obtained.

The second protrusion 42 is arranged below the light-emitting device 20 (that is, on the side opposite to the side of light extraction) in the light-emitting module. Therefore, the second protrusion 42 can be light-transmissive to the light emitted from the light-emitting device 20, or the second protrusion 42 does not necessarily have to be light-transmissive. Same as the first protrusion 41, the second protrusion 42 can be used as a dam for blocking the uncured covering member 50 in the production process. For this reason, it is preferable for the light-transmissive resin to be arranged in the same process as the first protrusion 41 or in a continuous process, and from the viewpoint of simplification of the production method, it is preferable to use the light-transmissive resin as in the first protrusion 41.

### Second Embodiment

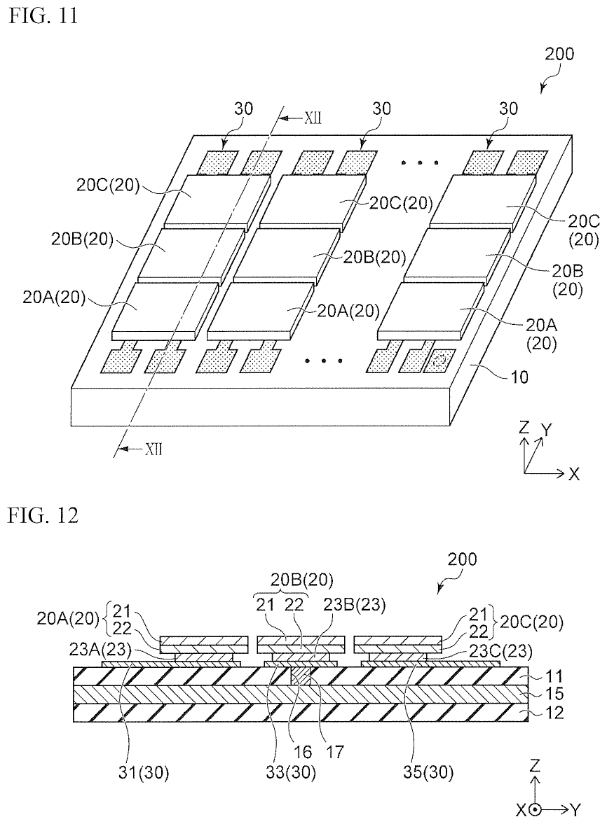

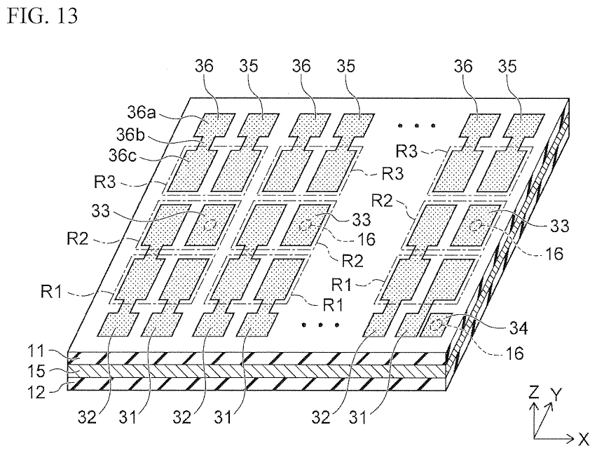

A light source 200 according to a second embodiment of the present disclosure will be described with reference to FIGS. 11 to 13. In the following description, differences from the first embodiment are mainly described. FIG. 11 is a schematic perspective view of the light source 200 according to the second embodiment. FIG. 12 is a schematic cross-sectional view taken along the line XII-XII in FIG. 11. FIG. 13 is a schematic perspective view illustrating a structure of a part of the light source 200.

The light source 200 according to the second embodiment is different from the first embodiment in that three light-emitting devices 20 are arranged along the Y direction. Specifically, a light-emitting device 20 includes a first light-emitting device 20A, a second light-emitting device 20B, and a third light-emitting device 20C. The light-emitting devices 20 are arranged on the upper surface of the wiring substrate 10 such that n combinations of the first light-emitting device 20A, the second light-emitting device 20B, and the third light-emitting device 20C arranged in this order along the Y direction are arranged along the X direction.

A wiring line 30 is arranged on a first insulating layer 11. The wiring line 30 includes a first wiring line 31, a second wiring line 32, a third wiring line 33, a fourth wiring line 34, a fifth wiring line 35, and a sixth wiring line 36. The first wiring line 31 to the fifth wiring line 35 are similar to those in the first embodiment. On the other hand, the sixth wiring line 36 includes a pad 36a to which a bonding wire for conducting electricity from the outside is connected, a terminal 36c to which a third cathode 23C2 of the third light-emitting device 20C is electrically connected, and a coupling portion 36b for coupling the pad 36a and the terminal 36c. The fifth wiring line 35 and the sixth wiring line 36 are arranged side by side along the X direction.

In this way, also in the light source 200 in which three light-emitting devices 20 are arranged along the Y direction, the wiring line can be arranged on the upper surface of the wiring substrate 10 while the wiring substrate 10 includes a conductor layer 15 having high thermal conductivity, and it is possible to provide a light source having high heat dissipation, which can be individually driven and controlled at low cost.

### Other Embodiments

Although the embodiments of the present disclosure have been described above, the present disclosure is not limited to them. For example, although the light source 100 to which the technical concept of the present disclosure is applied has been described in the embodiments described above, the technical concept of the present disclosure can also be applied to the wiring substrate 10. That is, the wiring substrate 10 includes a conductor layer 15, a first insulating layer 11 arranged on an upper surface of the conductor layer 15, and a first wiring line 31, a second wiring line 32, a third wiring line 33, and a fourth wiring line 34 arranged on the first insulating layer 11. The first insulating layer 11 includes one or more through holes 16, and the through holes 16 include metal members 17 arranged inside. The third wiring line 33 and/or the fourth wiring line 34 is electrically connected to the conductor layer 15 via the metal members 17 arranged inside the through holes 16. The wiring substrate 10 can accommodate a first light-emitting device 20A including a first anode 23A1 and a first cathode 23A2, and a second light-emitting device 20B including a second anode 23B1 and a second cathode 23B2. The first wiring line 31 is electrically connectable to the first anode 23A1, the second wiring line 32 is electrically connectable to the first cathode 23A2 and the second anode 23B1, and the third wiring line 33 is electrically connectable to the second cathode 23B2. With such a configuration, it is also possible to provide the wiring substrate 10 having a similar effect as in the above-described embodiments.

Note that, although the light emission control of the light source 100 has been described in the embodiments described above, the present disclosure is not limited to this aspect. For example, although the conductor layer 15 is connected to the ground via the fourth wiring line 34 in the above embodiment, the conductor layer 15 can be connected to a power supply having a predetermined potential via the fourth wiring line 34. In this case, the first anode 23A1 and the first cathode 23A2 of the first light-emitting device 20A can be replaced with each other, the second anode 23B1 and the second cathode 23B2 of the second light-emitting device 20B can be replaced with each other, and Low and High levels of the first potential V1 and the second potential V2 can be replaced with each other. In this way, the first light-emitting device 20A and/or the second light-emitting device 20B can emit light.

Embodiments according to the present disclosure have been described above with reference to specific examples. However, the present disclosure is not limited to these specific examples. All aspects that can be practiced by a person skilled in the art modifying the design as appropriate based on the above-described embodiments of the present disclosure are also included in the scope of the present disclosure, as long as they encompass the spirit of the present disclosure. Furthermore, within the scope of the technical concept of the present disclosure, a person skilled in the art may conceive various alternative embodiments and variations, and those alternative embodiments and variations also fall within the scope of the present disclosure.

1. A light source comprising:
a wiring substrate;
a first light-emitting device; and
a second light-emitting device, wherein
the wiring substrate comprises:
a conductor layer;
a first insulating layer arranged on an upper surface of the conductor layer; and
a first wiring line, a second wiring line, a third wiring line, and a fourth wiring line arranged on the first insulating layer, and
the first light-emitting device and the second light-emitting device are arranged on an upper surface of the wiring substrate,
the third wiring line and the fourth wiring line are electrically connected to the conductor layer,
the first light-emitting device comprises a first anode and a first cathode,
the second light-emitting device comprises a second anode and a second cathode,
the first anode is electrically connected to the first wiring line,
the first cathode and the second anode are electrically connected to the second wiring line, and
the second cathode is electrically connected to the third wiring line.

2. The light source according to claim 1, wherein
the first wiring line comprises a pad, and
in a plan view, the pad of the first wiring, the first anode of the first light-emitting device, and the second cathode of the second light-emitting device are arranged along a first direction.

3. The light source according to claim 2, wherein
the second wiring line comprises a pad,
in a plan view, the first wiring line and the second wiring line are arranged side by side along a second direction orthogonal to the first direction, and
the pad of the second wiring line, the first cathode of the first light-emitting device, and the second anode of the second light-emitting device are arranged along the first direction.

4. The light source according to claim 1, wherein
the wiring substrate further comprises a second insulating layer arranged on a lower surface of the conductor layer.

5. The light source according to claim 1, further comprising a third light-emitting device arranged on the upper surface of the wiring substrate, wherein
the first light-emitting device, the second light-emitting device, and the third light-emitting device are arranged along a first direction.

6. The light source according to claim 1, further comprising a third light-emitting device and a fourth light-emitting device arranged on the upper surface of the wiring substrate, wherein
the wiring substrate further comprises a fifth wiring line, a sixth wiring line, and a seventh wiring line arranged on the first insulating layer,
the seventh wiring line is electrically connected to the conductor layer,
the first light-emitting device, the second light-emitting device, the fourth light-emitting device, and the third light-emitting device are arranged along a first direction,
the third light-emitting device comprises a third anode and a third cathode,
the fourth light-emitting device comprises a fourth anode and a fourth cathode,
the third anode is electrically connected to the fifth wiring line,
the third cathode and the fourth anode are electrically connected to the sixth wiring line, and
the fourth cathode is electrically connected to the seventh wiring line.

7. The light source according to claim 6, wherein
the first insulating layer comprises one or more through holes,
the through holes comprise metal members arranged inside, and
the third wiring line, the fourth wiring line, and the seventh wiring line are electrically connected to the conductor layer via the metal members arranged inside the through holes.

8. A wiring substrate comprising:
a conductor layer;
a first insulating layer arranged on an upper surface of the conductor layer; and
a first wiring line, a second wiring line, a third wiring line, and a fourth wiring line arranged on the first insulating layer, wherein
the first insulating layer comprises one or more through holes,
the through holes comprise metal members arranged inside,
at least one of the third wiring line or the fourth wiring line is electrically connected to the conductor layer via the metal members arranged inside the through holes,
the wiring substrate can accommodate:
a first light-emitting device comprising a first anode and a first cathode; and
a second light-emitting device comprising a second anode and a second cathode,
the first wiring line is electrically connectable to the first anode,
the second wiring line is electrically connectable to the first cathode and the second anode, and
the third wiring line is electrically connectable to the second cathode.

9. The wiring substrate according to claim 8, wherein
the third wiring line is electrically connected to the conductor layer via the metal members arranged inside the through holes, and
the fourth wiring line is not electrically connected to the conductor layer via the metal members arranged inside the through holes.

10. The wiring substrate according to claim 8, wherein
the third wiring line is not electrically connected to the conductor layer via the metal members arranged inside the through holes, and
the fourth wiring line is electrically connected to the conductor layer via the metal members arranged inside the through holes.

11. The wiring substrate according to claim 8, wherein
both the third wiring line and the fourth wiring line are electrically connected to the conductor layer via the metal members arranged inside the through holes.

12. The wiring substrate according to claim 8, wherein
the first wiring line comprises a pad.

13. The wiring substrate according to claim 12, wherein
the second wiring line comprises a pad.

14. The wiring substrate according to claim 8, wherein
the wiring substrate further comprises a second insulating layer arranged on a lower surface of the conductor layer.

15. The wiring substrate according to claim 8, further comprising a fifth wiring line, a sixth wiring line, and a seventh wiring line arranged on the first insulating layer, wherein
the wiring substrate can accommodate:
a third light-emitting device comprising a third anode and a third cathode; and
a fourth light-emitting device comprising a fourth anode and a fourth cathode,
the seventh wiring line is electrically connected to the conductor layer,
the fifth wiring line is electrically connectable to the third anode,
the sixth wiring line is electrically connectable to the third cathode and the fourth anode, and
the seventh wiring line is electrically connectable to the fourth cathode.

16. The wiring substrate according to claim 15, wherein
the first insulating layer comprises one or more through holes,
the through holes comprise metal members arranged inside, and
the third wiring line, the fourth wiring line, and the seventh wiring line are electrically connected to the conductor layer via the metal members arranged inside the through holes.
